(19) United States
(12) Patent Application Publication
(10) Pub. No.: US 2021/0341835 A1
(43) Pub. Date: Nov. 4, 2021

(54) Production of Three-Dimensional Structures by Means of Photoresists

(71) Applicant: Laser Imaging Systems GmbH, Jena (DE)

(72) Inventors: Jens THEIS, Duisburg (DE); Frank BIERAU, Jena (DE)

(21) Appl. No.: 17/244,858

(22) Filed: Apr. 29, 2021

(30) Foreign Application Priority Data
Apr. 30, 2020 (DE) 10 2020 111 895.3

(51) Int. Cl. G03F 7/00; G03F 7/20; G03F 7/004; G03F 7/42; G03F 7/16; C25D 3/02

(52) U.S. Cl. CPC G03F 7/0037; G03F 7/2026; G03F 7/0041; C23C 30/005; G03F 7/161; C25D 3/02; G03F 7/422

(57) ABSTRACT

A process for the production of three-dimensional structures involves generating stepped structures in the micrometer to millimeter range. A novel possibility for realizing microstructures for micromechanical and high-performance electronic structures allows a substantially free shaping of and high-throughput production of stepped structures is met according to the invention by coating a copper-clad substrate at least once with a first photoresist for generating a defined height of at least one structure step and coating the first photoresist at least once with a second photoresist for generating a defined height of at least one further structure step, wherein the first photoresist and the second photoresist have different photosensitivities and transmission characteristics which generate structure-forming regions at least of the first photoresist and second photoresist by exposing with different wavelengths and radiation doses and after developing. The structure-forming regions at least partially overlap one another and form a stepped three-dimensional structure.

### RELATED APPLICATIONS

This application claims priority to German Patent Application DE 10 2020 111 895.3, filed Apr. 30, 2020, which is incorporated herein by reference in its entirety.

### FIELD OF THE INVENTION

The invention is directed to a process for the production of three-dimensional structures by means of photoresist, particularly for generating stepped structures from photoresist or for molding molded bodies by means of stepped structures in the micrometer to millimeter range. The field of use of the invention is particularly in the electronics industry in printed circuit board packaging and chip packaging, in the semiconductor industry and in microtechnology, particularly for producing micromechanical structures.

### BACKGROUND OF THE INVENTION

Photoresist is used in the prior art for photolithographic patterning in order to generate structures in the micrometer and submicrometer range in microelectronics and microsystems technology. The procedure is always carried out by applying a photoresist layer to a substrate or to an already existing circuit structure layer and subsequently exposing it in the regions which—with a negative resist—are to be retained as structure surfaces, or exposing it in regions which—with a positive resist—are to be ablated. The non-resistant regions in the subsequent development process of photoresist structures are removed as uncured layer components and can subsequently be filled with electronic conductor structures and semiconductor structures or locally occupied by gate structures.

A procedure of this kind was described by V. Papageorgiou et al. in the technical article “Cofabrication of Planar Gunn Diode and HEMT on InP Substrate (IEEE Transactions on Electron Devices, Volume 61, no. 8[2014] 2779 - 82784). The gate gap between source and drain required in this context for a Gunn diode or HEMT (high-electron mobility transistor) structure with a width of 1.5 μm to 2 μm was produced by ablated photoresist structures. Because of the small thickness of the source layer and drain layer, only photoresist layer thicknesses on the order of approximately 0.1 μm are needed. The photoresists used for the diode structure require different photoresist sensitivities which are brought about by a different percentage of the PMMA (poly[methyl methacrylate]) component in order to achieve different ablation depths. As concerns possibilities for producing structures in which the layer thicknesses are on the order of magnitude of the structure widths or beyond, there are no suggestions or insights disclosed in the above-cite technical article for viable larger ablation depths at investments of energy or time required for this.

### SUMMARY OF THE INVENTION

The invention has the object of finding a novel possibility for realizing microstructures for micromechanical and high-performance electronic structures which allow a substantially free shaping of stepped, particularly overhanging, structures and a flexible, high-throughput production of complicated shapes for forming metallic microstructures and conductive traces.

According to the invention the above-stated object is met in a process for the production of three-dimensional structures by means of photoresist having the following steps:

providing a metal-clad substrate (1) for improving the surface adhesion or adaptation for subsequent metal deposition and separation of structures (6; 71) from the substrate (1);

coating (3) the copper-clad substrate (1) at least once with a first photoresist for generating a defined height of at least one structure step and coating (3) the first photoresist at least once with a second photoresist for generating a defined height of at least one further structure step, wherein the first photoresist and the second photoresist have different photosensitivities and transmission characteristics for a patterning;

exposing (4) the first photoresist with an exposure radiation (41) with a first wavelength range and a first radiation dose in at least one structure-forming region (35) of the first photoresist;

exposing at least the second photoresist with exposure radiation (42) with a second wavelength range and a second radiation dose in at least one structure-forming region (36) of the second photoresist, wherein the structure-forming regions (35; 36) of at least the first photoresist and second photoresist at least partially overlap one another;

developing (5) at least one multi-layer photoresist structure (6) from the overlapping structure-forming regions (35; 36; 37) at least of the first photoresist and second photoresist by developing the non-structure-forming exposed regions of the coatings (31; 32; 33; 34) of at least the first photoresist and second photoresist.

The coating of the first photoresist with the second photoresist is advantageously carried out before the first structure-generating exposure of the first photoresist and the structure-generating exposure of the second photoresist.

Alternatively, the coating of the first photoresist with the second photoresist can be carried out only after the structure-generating exposure of the first photoresist and the structure-generating exposure of the second photoresist after coating with the second photoresist.

In a further advantageous variant, the coating of the second photoresist with a third photoresist is carried out only after the structure-generating exposure of the second photoresist, and the coating with a fourth photoresist or any further photoresist is preceded by the structure-generating exposure of the third photoresist or any further previously applied photoresist.

In a preferred execution of the process, at least the first photoresist or the second photoresist or a further photoresist with more than one photoresist layer is applied one above the other in order to generate a desired defined height of a structure step of the photoresist structure.

Further, it is advisable that the first photoresist and the second photoresist are selected with a different sensitivity in each instance such that they can be cured with a different exposure radiation to which the other respective photoresist does not react.

A preferred variant consists in that the first photoresist is sensitive to a longer-wavelength exposure radiation with higher exposure dose relative to effective wavelength and exposure dose of the second photoresist and insensitive relative to a shorter-wavelength exposure radiation with lower exposure dose to which the second photoresist reacts, and the second photoresist is transparent and insensitive relative to the longer-wave exposure radiation and higher exposure dose of the first photoresist and is sensitive to exposure radiation with a shorter wavelength relative to the effective wavelength and exposure dose of the first photoresist.

The different sensitivities of the first photoresist and of the second photoresist in a wavelength range of 375 nm and 436 nm advisably differ by more than 20 nm, preferably by more than 30 nm, and by a range between 10 mJ/cm² and 2200 mJ/cm², preferably by a factor of more than 4, in the applicable dose.

A third photoresist or further photoresist is advantageously selected with a sensitivity such that it differs in wavelength in a wavelength range of 248 nm and 436 nm by more than 20 nm, preferably by more than 30 nm, from the wavelengths of the first photoresist and second photoresist and differs in the applicable dose by a range between 10 mJ/cm² and 2200 mJ/cm², preferably by a factor of more than 4, from the applied exposure doses of the first photoresist and second photoresist.

It has proven advantageous when, during the development of at least the first photoresist and second photoresist, three-dimensional photoresist structures of overlapping structure-forming regions of at least the first photoresist and second photoresist remain on the substrate and form photoresist gaps between adjacent photoresist structures which are usable as cavities for filling with a moldable material.

In this regard, a metal or a metal alloy can be deposited into the photoresist gaps between adjacent or surrounding photoresist structures.

At least one of the metals from the group including copper, nickel, titanium, chromium, aluminum, palladium, tin, silver and gold or alloys thereof is advisably used as filling material for the cavities.

The photoresist structures are preferably generated as elongated layer stacks which are spaced apart by gaps or as layer stacks enclosed by a gap in order to mold different molded bodies in the gaps.

After a metal deposition in the gaps which are brought about between the photoresist structures by development of at least the first photoresist and second photoresist, a removal of the photoresist structures can advisably be carried out by means of a resist developer in which shaped metal molded bodies remain on the metal layer of the metal-clad substrate.

A process of metal etchback of the metal layer on the substrate can advantageously be carried out by means of a metal etchant at least in the intermediate spaces between the metal structures formed by the metal deposition.

In a particularly advantageous application, the process of metal etchback with etchants adapted to the metal layer of the metallized substrate can be continued until the metal layer of the substrate is completely ablated so that the metal structures are singulated as metal molded bodies.

The invention shows a possibility for realizing microstructures for micromechanical or high-performance microelectronic structures which allow a substantially free shaping of stepped, particularly overhanging, structures and a flexible, high-throughput production of complicated shapes for forming metallic micro-molded articles.

### BRIEF DESCRIPTION OF THE DRAWINGS

The invention will be described more fully in the following referring to embodiment examples and illustrations. The drawings show:

FIG. 1 a schematic diagram showing the process according to the invention for generating an advantageously stepped structure with different photoresist layers;

FIG. 2 a schematic diagram showing the process according to the invention for generating a further advantageously stepped structure with different photoresist layers;

FIG. 3 a schematic diagram showing a further embodiment of the process according to the invention for generating a three-layer structure with at least two different photoresists;

FIG. 4 a schematic diagram of the process according to the invention for continuing the execution according to FIG. 3 for generating a six-layer structure with a total of at least three different photoresists;

FIG. 5 an advantageous continuation of the execution of the process according to the invention according to FIGS. 3 and 4 in which the multiply-generated photoresist structures are used for producing metallic molded bodies and a singulation (detachment from the substrate) of the molded bodies is carried out;

FIG. 6 a schematic diagram of a further execution of the process according to the invention for generating a structure with at least two different photoresists in which an exposure is carried out for each of the different photoresists in each instance prior to the exposure with the next photoresist;

FIG. 7 an advantageous continuation of the process according to the invention from FIG. 6 in which the multiply-generated resist structures are used for producing metal structures, wherein an etchback of the copper coating of the substrate can be carried out either only for electrically isolating the separate metal structures or until metal molded bodies can be singulated (detached from the substrate);

FIG. 8 a schematic diagram showing a further execution of the process according to the invention for generating thick photoresist layers in which the separate exposure is carried out for different photoresists and the gaps of the structures are filled with copper after the development of the resist structures in order to obtain separated copper structures on the substrate after etchback of the metallization of the substrate (or of the substrate itself);

FIG. 9 a selection of easily realizable cross sections of preferred photoresist structures for multiple production of microstructures using a limited quantity of different photoresist layers which are producible with an individual conjoint development step.

### DETAILED DESCRIPTION OF THE PREFERRED EMBODIMENTS

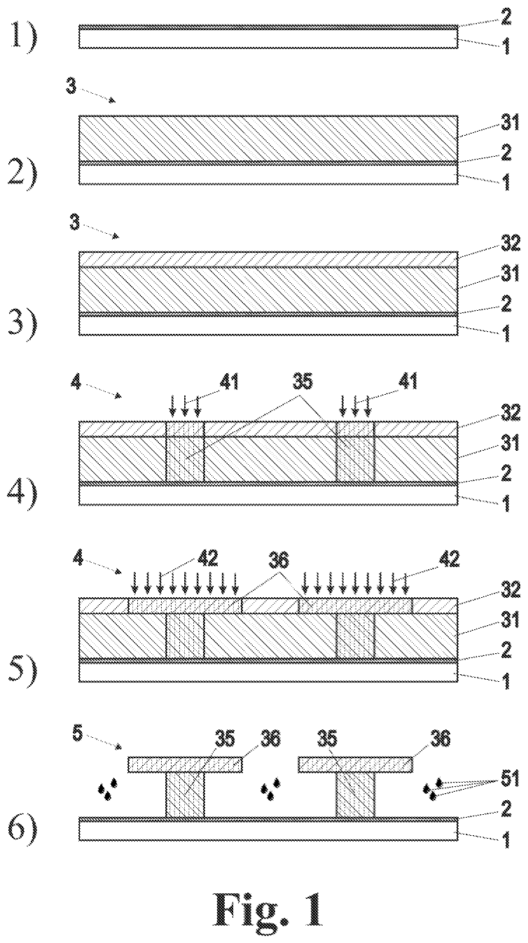

The process according to the invention for generating microstructures with structure heights (layer thicknesses) in the lower to upper micrometer range (1 μm to several hundred μm) in a basic variant according to FIG. 1 comprises the following steps:

providing a metallized substrate 1 (generally: metal cladding, PVD metallization or metal deposition;

coating 3 the metal-clad substrate 1 at least once with a first photoresist for generating at least one defined step height of a structure step and coating 3 the first photoresist at least once with a second photoresist for generating at least one further structure step, wherein the first photoresist and the second photoresist have different photosensitivities and transmission characteristics for a patterning;

first structure-generating exposure 4 for the first photoresist with a first wavelength range and a first radiation dose;

second structure-generating exposure 4 for the second photoresist with a second wavelength range and a second radiation dose;

developing 5 a multi-step photoresist structure 6 by ablating the non-structure-forming exposed regions of the first photoresist and second photoresist.

In this regard, there are hardly any limits to the kind of structure configuration with respect to quantity, height and width of the edges. However, for the achievable edge quality at the end of the development process of the photoresist structure depending on the desired height of the structure steps, the materials of the photoresists are to be selected based on the spectral sensitivity thereof and the absorption/transmission characteristics of the utilized photoresists for the machining beam. Additionally, there are the available radiation outputs and radiation doses for achieving the structure-generating exposure within the sensitivity range of the utilized photoresists within the shortest possible exposure times.

FIG. 1 shows the individual steps in a schematic profile view of a layer stack generated on a substrate 1. A substrate 1 is provided with a metal layer 2 (metal cladding) in portion 1 as starting point for the required generation of microstructures. The metal layer 2 serves primarily to improve the surface adhesion for further coatings, for subsequent metal deposition processes and processes for detaching structures from the substrate 1.

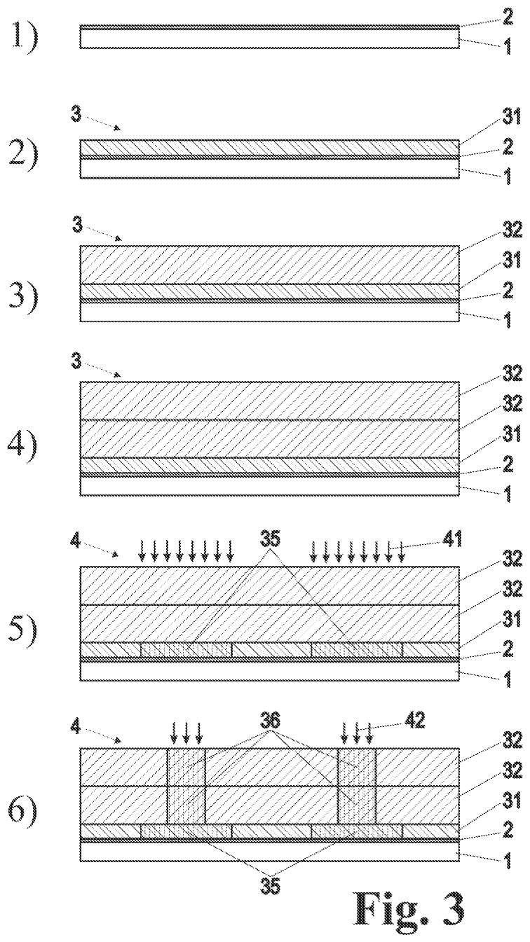

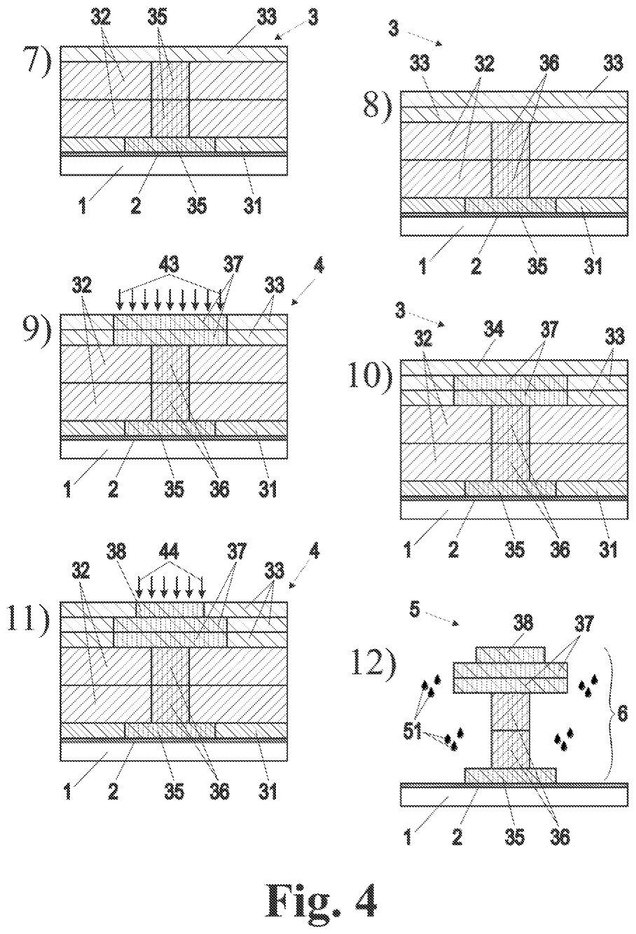

Portion 2 of FIG. 1 shows the substrate 1 after coating with a first photo resist 31 (e.g., photopolymer A) which has a layer thickness which is adapted to a desired height of the structure to be generated. In case a defined uniform layer application is not possible in one step, the required layer thickness can also be carried out through multiple coating with the same photoresist 31 as will be shown more fully later (e.g., FIGS. 3 and 4).

The selection of the photoresist is basically oriented to the final shape of the structure to be generated. The characteristics of the photoresists utilized for processing are the wavelength-dependent absorption/transparency and sensitivity (exposure dose). These characteristics must be suitably adapted to one another for the respective structure.

The generation of T-shaped structures, for example, from polymers for the purpose of subsequent metal shaping, as is assumed and shown in FIG. 1, requires as lower photoresist layer 31 a first photoresist (e.g., Hitachi HM-40112) which reacts to relatively large wavelengths, e.g., 402 nm, and requires a high exposure dose (e.g., 250 to 400 mJ/cm² at 405 nm) for curing to the full depth of the photoresist layer 31. The Hitachi RY series, Hitachi HM series and DuPont WBR series, for example, with suitable exposure wavelengths for curing are also applicable as insensitive photoresists of the kind mentioned above.

In contrast, the overlying photoresist layer 32 requires distinctly different characteristics when different cross-sectional dimensions and/or height dimensions are to be generated for the final shape of the structure. For the shape selected in FIG. 1 which protrudes in a T-shaped manner, a photoresist (e.g., Kolon Industries LS-8025) with a high absorption for short wavelengths (e.g., 375 nm) and a high transparency for the long wavelengths used for exposure of the first photoresist layer 31 and an exposure dose which is as low as possible (e.g., Kolon Industries LS-8025: 35 to 50 mJ/cm² at 375 nm) for curing is to be selected for the upper photoresist layer 32. The Hitachi RD series, Hitachi SL series, Asahi Kasei AQ series and Kolon Industries LS series, for example, are suitable as highly sensitive photoresists of this kind.

The photoresists are to be selected with parameters which differ from each other such that the exposure processes with the exposure radiation 41 for the first structure-forming region 33 of the photoresist layer 31 provided for curing, as is shown in portion 4, and with the exposure radiation 42 for the second structure-forming region 34 of photoresist layer 32 selected for curing, as is shown in portion 5, are as far as possible limited only to that layer for which they are determined. This is important in order that particularly those portions of the structure-forming regions 33 and 34 of photoresist layers 31 and 32 to which the two exposure radiations 41 and 42 are directed are only influenced by the exposure radiation 41 or 42 intended for them, so that consistent degrees of cure which allow an edge-specific precise ablation of the uncured residual portions of the photoresist layers 31 and 32 in the subsequent development process according to portion 6 of FIG. 1 can be achieved within the respective structure-forming region 33 and 34 of the first and second photoresist layers 31 and 32, respectively.

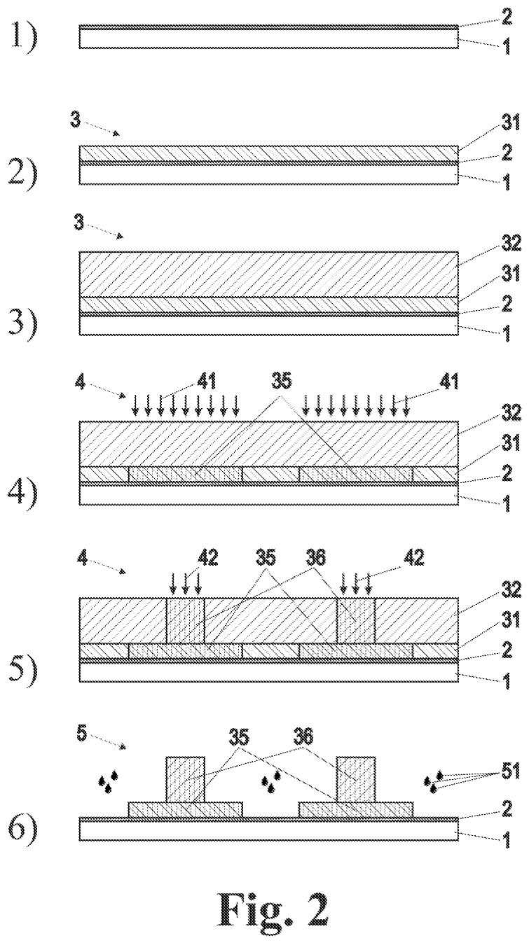

With an inverted T-shaped structure as is shown in FIG. 2, an inversion of the characteristics of the first and second photoresist layers 31 and 32 previously described referring to FIG. 1 is needed. The lower photoresist layer 31 requires a first photoresist with low exposure dose and a higher sensitivity to long wavelengths (e.g., Hitachi SL-1338 with 30 to 50 mJ/cm² at 405 nm). On the other hand, the upper photoresist layer 32 should have a second photoresist for a high exposure dose and with high transparency for long wavelengths (e.g., Hitachi RY-5125 with 180 to 300 mJ/cm² at 375 nm).

All of the rest of the sequences for executing the process according to FIG. 2 remain unchanged from FIG. 1. Only the first photoresist selected for the shape of the structure, the second photoresist conforming to the latter and the exposure radiations 41 and 42 which are selected to be adapted to the latter are changed. In principle, the material pairing of the photoresist layers 31 and 32 which is selected in FIG. 1 could also be applied in inverted manner and cured with adapted models of the exposure radiations 41 and 42 in case this is permitted by the transparency of the second photoresist layer 32 in the wavelength range of the exposure radiation 41 for the first photoresist layer 31.

A substantial advantage and the core of the process according to the invention is reflected in the embodiments of FIGS. 1 and 2 (and all of the following embodiment examples) in that coating and exposure processes and the developing process can take place in uniform (i.e., not alternately executed) cycles so that the coated substrate 1 need not repeatedly change the specific processing chambers required therefor and, because of this process economics, large quantities of desired three-dimensional microstructures can be produced with a high process throughput with methods known from chip production.

FIG. 3 shows a further embodiment of the process according to the invention using a first photoresist and a second photoresist differing from the first photoresist. In this case, because of the desired structure height of the second photoresist, the photoresist layer 32 is applied twice—as is shown in steps in portions 1 to 4—after the coating of the substrate 1 on the metal coating 2 (e.g., copper cladding) with the lower photoresist layer 31. A multiple coating of this kind prior to the action of the exposure radiation 41 and 42 for the first photoresist and second photoresist in a serial exposure cycle is always only possible provided the two photoresist layers 32 (e.g., comprising Hitachi RY-5125) have a sufficient transparency in the wavelength of the exposure radiation 41 (e.g., 405 nm) for the first photoresist (e.g., Hitachi SL-1338) and the latter is curable at a low exposure dose (e.g., at 30 to 50 mJ/cm²) as is shown schematically in portion 5. After the exposure process according to portion 6 of FIG. 3 with the second exposure radiation 42 (e.g., with 200 to 300 mJ/cm² at 375 nm) for the second photoresist (e.g., Hitachi RY-5125) of the two upper photoresist layers 32, the process of structure generation with the developing process (corresponding to portion 6 from FIG. 2) can be concluded or—as intended herein—a more complex shape of a structure can be generated with further photoresist coatings.

FIG. 4 shows an advantageous continuation of the process variant of FIG. 3 for generating two further structure steps of a desired structure. The same could be required when the desired structure should have exclusively a greater height. In portion 7 of FIG. 4 which is consecutively numbered referring to FIG. 3, a further photoresist layer 33 is applied in a two-fold manner in order to generate a further edge structure (structure step) without a prior developing process for the layer stack which has been applied and exposed up to this point and which comprises lower photoresist layer 31 and two upper photoresist layers 32 located thereon. The multiple layer application is not contingent upon the desired (rather low) structure height but rather is required for preventing the effect on the photoresist layers 31 and 32 located below it, since a third photoresist with a low exposure dose (e.g., JSR THB-111N with 25 mJ/cm² at 355 nm) is to be selected. The wavelength for curing the third photoresist must likewise be selected differently compared to the first and second photoresists. However, if the exposure dose for layer 33 is low enough and the absorption is high enough, the same wavelength can be used as that used for layer 31. After the two photoresist layers 33 have been applied, they are subsequently cured within the structure-forming region 35 by means of an exposure radiation 43 as is shown in a stylistic manner in portion 9 with short wavelength and low exposure dose for the third photoresist, e.g., 355 nm at 25 mJ/cm² (as indicated above) or, alternatively, 375 nm at 35 mJ/cm² for Kolon Industries LS-8025.

Further, it is assumed for the example shown in FIG. 4 that a further gradation of the desired structure profile according to portion 10 is provided in such a way that a final photoresist layer 34 is applied with a further photoresist which may be identical to the third photoresist (e.g., JSR-THB-111N: [e.g., 25 mJ/cm² at 355 nm]) when structure-forming region 38 is smaller than the structure-forming regions 37 of photoresist layers 33.

However, in case the dimensioning of the structure-forming region 38 of the final photoresist layer 34 is larger, i.e., should have an overhang relative to the structure-forming regions 37 (not shown in FIG. 4), a fourth photoresist (e.g., JSR ARX series, 15 mJ/cm² at 248 nm) would have to be selected which again has a different wavelength (at least with respect to the third photoresist of layers 33) and requires a small radiation dose for curing in order to prevent impairment of the underlying photoresist layers 31, 32 and 33 outside of the structure-forming regions 35, 36 and 37.

After the curing—shown in portion 11 of FIG. 4—of the final photoresist layer 34 by means of the exposure radiation 44 which can correspond to the exposure radiation 43 in the above-mentioned first instance of the smaller structure-forming region 38, a conjoint development process for all of the photoresist layers 31 to 34 takes place according to portion 12 by means of the usual developers 51, e.g., alkaline developers (sodium carbonate, potassium carbonate, potassium hydroxide, tetramethylammonium hydroxide, etc.) or organic developers (1-methoxy-2-propylacetate, cyclopentanone, etc.), after which the desired structure 6 remains.

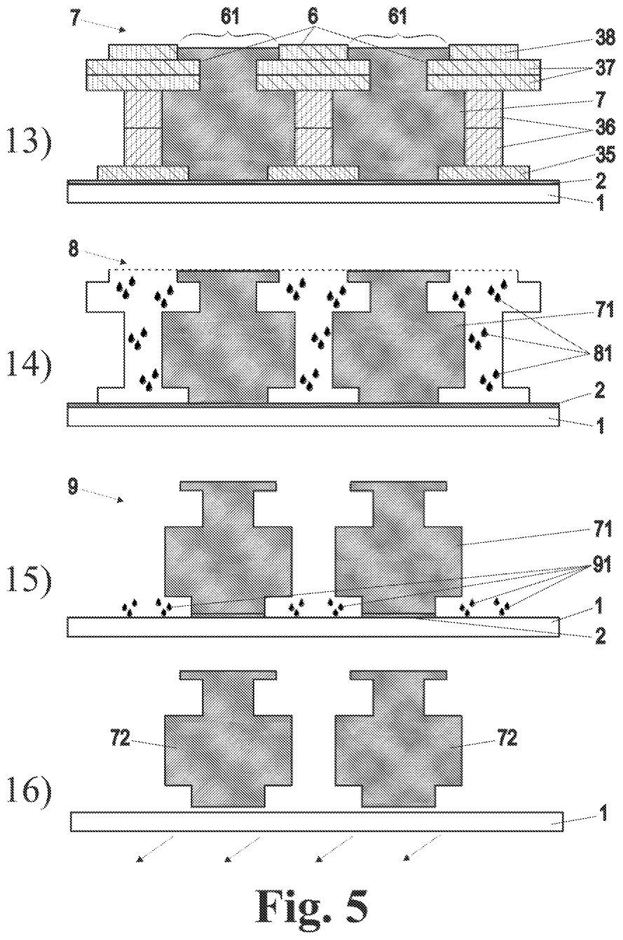

FIG. 5 shows a preferred application for the structure 6 produced in the process according to FIGS. 3 and 4 in which it is assumed that a multiple production of the structure 6 is carried out on the substrate 1 occupied by a metal layer 2. Portion 13 of FIG. 5 shows such a section of the substrate 1, wherein a metal deposition 7 (e.g., of copper, nickel, chromium, tin, palladium, silver, gold or alloys thereof) is carried out between two adjacent structures 6 in each instance until the photoresist gaps 61 are completely filled. In order to protect the metal depositions 7 during the subsequent etchback process, it may be advantageous to select a substrate 1 which dissolves in an organic solvent and which is accordingly not corrosive for the metal of the metal deposition 7. For this purpose, it would be useful to incorporate an additional thin separating layer (not shown here) made from a polymer between substrate 1 and metal layer 2.

Portion 14 of FIG. 5 shows the following step of uncovering molded metal depositions 7 between the structures 6 of photoresist layers 31 to 34 (designated only in FIGS. 4 and 5). The structures 6 utilized in this case as negative molds for shaping the metal deposition 7 are dissolved away for this purpose in that a resist developer 81 acts on the structure-forming regions 35 to 38 of the photoresist layers 31 to 34 in a process step of resist removal 8, and the photoresist structures 6 between the photoresist gaps 61 which were filled with metal in the meantime are dissolved away. Thereafter, the metal depositions 7 which are molded into the photoresist gaps 61 and which are still fixedly connected to the substrate 1 via the metal layer 2 of the substrate 1 remain on the metal-clad substrate 1.

If the metal depositions 7, as metal structure 71 (only designated in portion 16), are to remain fixedly bonded to the substrate 1 but electrically isolated from one another, a metal etchback 9 is carried out to a limited extent such that only the metal cladding of the substrate 1 is ablated by a resist developer 81 (e.g., iron(III) chloride or copper(II) chloride together with hydrogen peroxide for copper, iron(III) chloride or nitric acid together with hydrochloric acid for nickel, ammonium hydroxide together with hydrogen peroxide and methanol for silver, diluted nitric acid for tin, etc.). The results are shown schematically in portion 15 of FIG. 5.

If it is desirable to singulate the metal structures 71, the process of metal etchback 9 is longer and/or continued with etchant (as indicated above) specifically adapted to the material of the metal layer 2 of the substrate 1 until the metal structures 71 have detached from the substrate 1 as individual metal molded bodies 72 as is shown in portion 16.

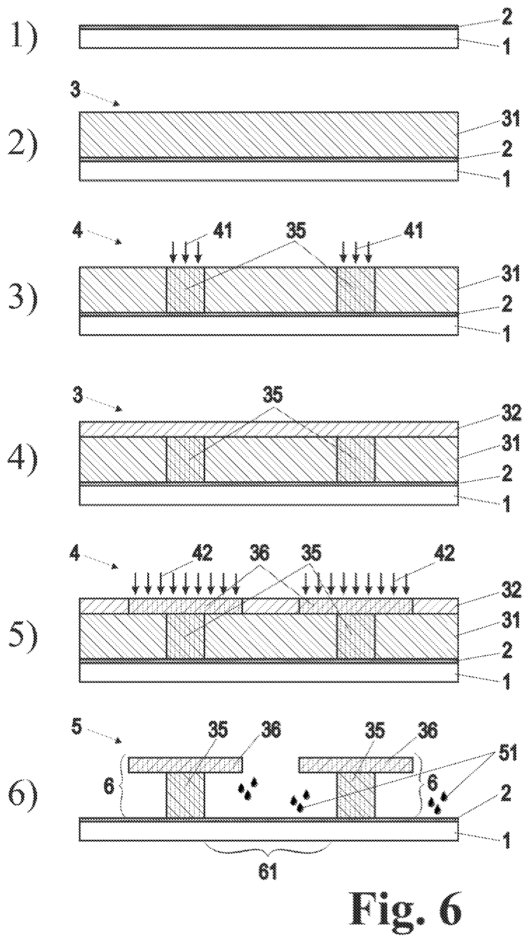

In six portions, FIG. 6 shows a further example for the production of a simple photoresist structure 6 in which only two photoresist layers 31 and 32 are required in order to generate a T-shaped structure 6 with the dimensions of width b: 100 μm, height h: 83 μm, supporting width s: 50 μm, supporting height (h-t): 45 μm.

The procedure differs from the embodiments according to FIGS. 1 and 2 in that after coating 3, according to portion 2, with the first photoresist (for example, DuPont Hitachi RY-5545 which is optimized for relatively short wavelengths of 365 nm [i-line of a mercury vapor lamp]), the resulting photoresist layer 31 is exposed (for example, initially with an exposure radiation 41 adapted thereto [e.g., 240 mJ/cm² at 375 nm]) in the structure-forming region 35 corresponding to portion 3 before a coating 3 according to portion 4 is carried out with the second photoresist which is sensitive to relatively large wavelengths (e.g., Hitachi SL-1333 at 405 nm).

If photoresist layer 32 is applied, it is subsequently exposed, according to portion 5, in the structure-forming region 36 with an exposure radiation 42 (e.g., 30 mJ/cm² at 405nm). Subsequently, the conjoint development process 5 is carried out with a selected resist developer 81 (e.g., based on alkaline solutions of sodium carbonate, sodium hydroxide, potassium carbonate or potassium hydroxide.

In order to generate an especially high width b simultaneous with a small supporting width s, it may be necessary to use a photoresist layer 31 with especially high sensitivity. An example of such a photoresist is AZ 125nXT which, for thicker layers starting from 70 μm, requires a dose of 1500 mJ/cm² to 2200 mJ/cm² for curing. Accordingly, the upper photoresist layer 32 can then be exposed with a dose which is four-times smaller, but which is appreciably higher than usual, in order to enhance the stability of this upper photoresist layer 32 and enable a larger overhang than the lower photoresist 31. In this example, the structure-forming region 36 (formed from the Hitachi SL-1333 resist) can be exposed with approximately 150 mJ/cm² instead of 30 mJ/cm². In contrast, the dose used for exposing the lower photoresist layer 31 was ten-times to almost fifteen-times the amount, so that the dose of less than one-tenth of a dose used for the upper photoresist layer 32 had no noticeable effect on the unexposed regions (outside of the structure-forming regions 35) of the lower photoresist layer 31.

In every case, the exposure doses of the lower to upper photoresist layers 31, 33 and 32, 34, respectively, should differ by a factor of four or more. This prevents an unwanted exposure of the other respective photoresist layer 32, 34 and 31, 33, respectively, outside of the structure-forming regions 35, 36 which have already been exposed. Since the exposure dose is substantially determined by the sensitivity of the selected resists, the factor of the dose differences can be selected smaller the farther apart the wavelength to which the respective resist is sensitive.

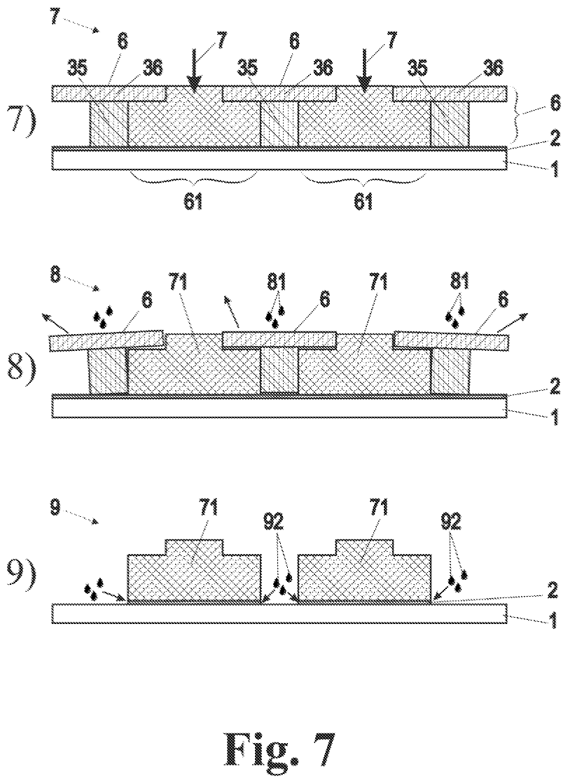

FIG. 7 shows a continuation of the process from FIG. 6 for the production of metallic structures 72 on the substrate 1, be it for the production of robust conductive traces for power electronics or of delicate conductive traces with enhanced mechanical stability. But intersecting photoresist structures 6 on the substrate are also curable by exposure so that gaps 61 are freed by the intersecting structure-forming regions 35 and 36 for metal depositions 71 having base areas which are square, rectangular, parallelogram-shaped, rhomboidal, hexagonal or in the range from elliptical to circular.

In order to clarify this process embodiment, portion 7 shows a section of the metal-clad substrate 1 with a metal layer 2 (e.g., of copper). Metal (as layers of, e.g., copper, nickel, chromium, tin, palladium, silver, gold or alloys thereof) are deposited in the gaps 61 resulting, according to portion 6 of FIG. 6, between the photoresist structures 6. Accordingly, the gaps 61 are completely filled and the metal deposition 7 is therefore correspondingly molded by utilizing the structure of gaps 61 as preform. According to portion 8, the photoresist structures 6 are completely dissolved away during the resist removal 8 by means of a resist developer 81 (e.g., potassium carbonate), and a metal etchback 9 is subsequently carried out for the metal layer 2 by applying an etchant 92 (as was mentioned above) which is suitably adapted for a partial metal etchback of the metal layer 2 between the metal structures 71. As a result, the substrate 1 remains with specifically shaped metal structures 71, the remaining portions of the metal layer 2 serving as adhesion promoters.

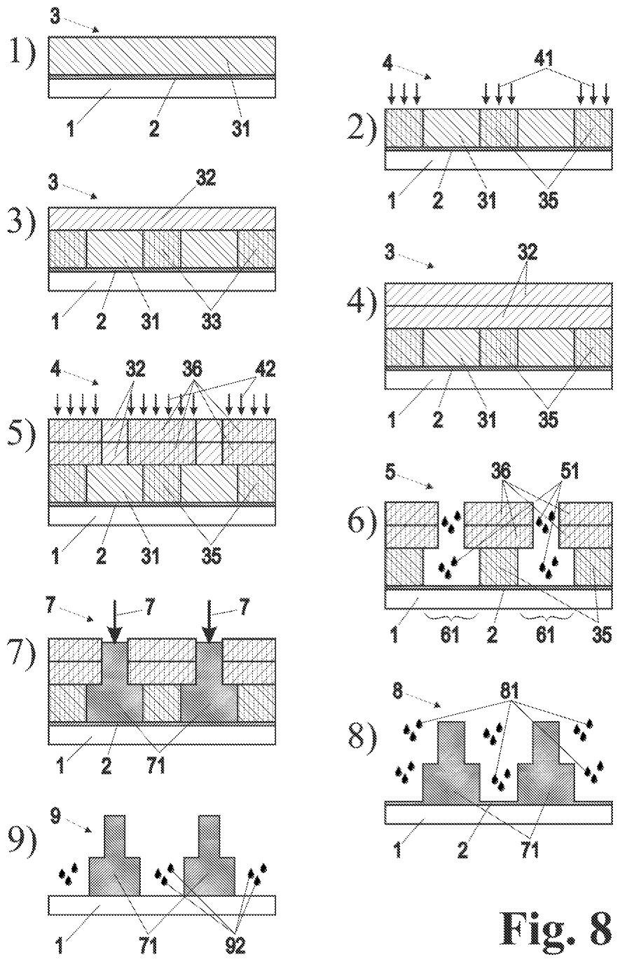

In the process variant shown in FIG. 8, the distinctive feature of the structure generation consists in generating particularly high T-shaped photoresist structures 6 in which the ratio of supporting height (h-t) to overall height h is approximately unity, and therefore an overhang of a structure-forming region 36 of a second photoresist is to be formed over the structure-forming region 35 of a first photoresist and, to save time, the photoresist structure 6 is to be generated from as few photoresist layers 31 and 32 as possible. The dimensions of the stepped T-shaped photoresist structure 6 in this example are assumed to be h=155 μm, b=90 μm, s=60 μm and (h-t)=75 μm.

For this purpose, a photoresist layer 31 which is produced from a first photopolymer (e.g., DuPont WBR-2075 or Hitachi HM-40112) for relatively large wavelengths, e.g., 405 nm, and a high exposure dose, e.g., 350 mJ/cm² at 405 nm, is applied to the metal-clad substrate 1 on the metal layer 2. A coating 3 with two identical photoresist layers 32 is required for the second overhanging structure step, and a second photoresist (e.g., Asahi Kasei AQ-4088) is used which has a high absorption for short wavelengths (e.g., 365 nm) and a high transparency for the long wavelengths utilized for the exposure of the first photoresist layer 31 and has the lowest possible exposure dose, (e.g., 80 mJ/cm² at 375 nm). Insofar as suitable lighting sources are available in the exposure device (not shown), a wavelength pairing of 405 nm and 355 nm can also be used, in which case, e.g., JSR THB-111N (with a small exposure dose of 25 mJ/cm² at 355 nm) can be used as second resist.

After coating 3 with the lower photoresist layer 31, as is shown in portion 1, the exposure 4 is advisably similarly carried out in this case in the desired structure-forming regions 35 (portion 2) with the exposure radiation 41 selected for the first photoresist before carrying out a second and third coating 3 with two like photoresist layers 32, according to portions 3 and 4, comprising the second photoresist. According to portion 5 of FIG. 8, the exposure 4 is then carried out in the provided structure-forming region 36 with the exposure radiation 42 adapted to the second photoresist. This is followed by the development 5 of all of the photoresist layers 31 and 32 jointly (portion 6). As was described in the preceding examples referring to FIGS. 5 and 7, a metal deposition 7 is carried out in the gaps 61 between the photoresist structures 6, whereby a metal structure 71 (e.g., comprising layers of copper, nickel, chromium, tin, palladium, silver, gold or alloys thereof) is molded at the photoresist structures 6. After resist removal 8 by means of a resist stripper 81 (e.g., by means of a 10-percent potassium hydroxide solution), a conducting connection formed by the metal layer 2 of the substrate 1 remains (according to portion 8) between the metal structures 71. In order to remove the latter and obtain the metal structures 71 as fixed structures on the substrate 1, a metal etchback 9 is carried out (portion 9) with an etchant 92 specifically adapted to the metal layer 2 (for example: copper(II) chloride together with hydrogen peroxide for Cu; a mixture of 5% nitric acid/65% phosphoric acid/5% acetic acid and water for Al; diluted nitric acid for Sn) for partial ablation of the metal layer 2 only between the desired metal structures 71.

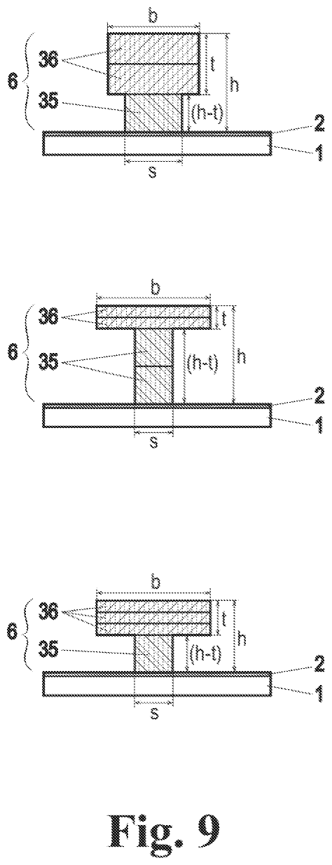

FIG. 9 once again shows specific advantageous photoresist structures 6 according to the process step of development 5. For clarification of the examples already described above, the dimensional measurements to be adjusted are indicated in portion 1.

The photoresist structure 6 shown in portion 1 of FIG. 9 is preferably designed for generating metal structures 71 or metal molded bodies 72 and generally has dimensions between h=30-1000 μm and (h-t)=10 μm-900 μm, where its width b and supporting width s can be selected virtually optionally but depending in each instance on the height and spacing of the structures and depending on the stability of the resist. Generating a plurality of like layers 31 and 32, respectively, when using only two different photoresists allows the structure height for individual structure steps to be increased up to a maximum of 1000 μm. Individual photoresist layers 31, 32 can sometimes have appreciably smaller heights (e.g., Hitachi SL series up to 76 μm, Hitachi HM-40112 up to 112 μm, DuPont WBR series up to 240 μm) and must be stacked, while there are also exceptions (e.g., MicroChem SU-8 up to 1000 μm) in which a large structure step can be achieved by means of only one photoresist layer 31. Since various dry film resists are only produced in determined layer thicknesses (e.g., Hitachi HM series in 56 μm, 75 μm and 112 μm), it may be necessary in certain cases to produce the desired layer thickness by lamination of multiple thin resist layers 31, 32. In this case, as in every other case, the exposure dose must be adapted to the respective layer thickness and the layer construction in order to obtain optimum results after development of the photoresist structures 6.

Portion 2 of FIG. 9 shows such a photoresist structure 6 which is preferably provided for generating metal structures 71 or metal molded body 72 having large gradations or projections (overhangs) of the cover surfaces (not shown) when there is a large height of the structure steps of the structure-forming regions 36 of the lower photoresist layer 31 and when there is a large overhang of the structure-forming regions 36 of the upper photoresist layer 32.

The metal structures 71 can serve for mechanical stabilization of conductive traces on flexible substrates 1. Through suitable selection of the structures 6 with respect to height, width and overhang, the mechanical stability under recurrent load is improved and the required amount of material in coating/depositing (plating) of the metal structures 71 is simultaneously reduced. This prolongs the useful life of metal baths for the deposition of metal layers. At the same time, the mechanical and electrical properties can be selectively adapted to the respective requirement by varying the size ratios of the metal structures 71.

Metal molded bodies 72 are used primarily as micromechanical elements or component parts which can be produced in large quantities by means of the technology utilized here.

With dimensioning similar to that in portions 1 and 2, portion 3 of FIG. 9 shows a specific layer configuration which is oriented in particular to a high ratio of width to supporting width. In this way, the generation of metal structures 71 in particular is improved with respect to mechanical stability and adhesion to flexible substrates 1.

A cost-effective and high-throughput generation of microstructures from photoresists or metals with reproducible accuracy and a limited quantity of process steps in one or a few cycles can be realized with the invention. Accordingly, a mass production with conventional technologies of the semiconductor industry and printed circuit board industry, but with an appreciably larger height dimension of the generated structures than in conventional circuit and wafer chip fabrication cycles, is possible for relatively delicate sharp-edged stepped bodies with reproducible edge quality and accuracy. By combining photoresist layers 31 to 34 comprising a few different photoresists of varying sensitivities for curing thereof, layer stacks can be assembled which are machinable in part in a continuous exposure cycle with different exposure wavelengths and/or exposure doses, but the photoresist structure 6 can be formed in every case in a conjoint development process. A particularly high level of process economics in the production of 3D microstructures in the one-digit to three-digit micrometer range is achieved in this way.

Further increases in the width of resist structures to be generated up to approximately 150 nm and structure heights into the millimeter range are possible when the process according to the invention is made applicable to steppers in the semiconductor industry in that the mercury vaper lamps which are conventional in the semiconductor industry are provided with filters for the wavelengths utilized here (365 nm, 405 nm, 436 nm). In addition, various laser light sources (solid-state lasers or laser diodes) with a wavelength of 355 nm, 375 nm or 405 nm can also be used. This process can also be applied to resists in the deep UV range which utilize a wavelength of 248 nm (KrF* lasers) and 193 nm (ArF* lasers) for exposure.

### REFERENCE NUMERALS

1 (metal-clad) substrate
2 metal layer
3 coatings
31, 32, 33 photoresist layer
34 final photoresist layer
35, 36, 37, 38 structure-forming region
4 exposure
41 exposure radiation (for photoresist layer 31)
42 exposure radiation (for photoresist layer 32)
43 exposure radiation (for photoresist layer 33)
44 exposure radiation (for photoresist layer 34)
5 development
51 developer
6 photoresist structure
61 (photoresist) gaps
7 metal deposition
71 metal structure
72 (metal) molded body
8 resist removal
81 resist developer (resist stripper)
9 metal etchback
91 metal etchant (for metal layer 2)
92 etchant for partial metal layer etchback

What is claimed is:

1. A process of producing three-dimensional structures comprising:
providing a substrate with metal cladding for improving surface adhesion or for adapting the substrate for subsequent metal deposition and separation of structures from the metal-clad substrate;
coating the metal-clad substrate at least once with a first photoresist for generating a defined height of at least one structure step, and coating the first photoresist at least once with a second photoresist for generating a defined height of at least one further structure step, the first photoresist and the second photoresist having different photosensitivities and transmission characteristics for patterning;
exposing the first photoresist with a first exposure radiation having a first wavelength range and a first radiation dose in at least a first structure-forming region of the first photoresist;
exposing at least the second photoresist with a second exposure radiation with a second wavelength range and a second radiation dose in at least a second structure-forming region of the second photoresist, wherein the first structure-forming region of the first photoresist and the second structure-forming region of the second photoresist at least partially overlap one another;
developing at least one multi-layer photoresist structure from the overlapping structure-forming regions at least of the first photoresist and second photoresist by developing the non-structure-forming exposed regions of coatings of the at least the first photoresist and second photoresist.

2. The process according to claim 1, wherein coating of the first photoresist with the second photoresist is carried out before exposing the first photoresist and before exposing the second photoresist.

3. The process according to claim 1, wherein coating of the first photoresist with the second photoresist is carried out after exposing the first photoresist and wherein exposing the second photoresist is carried out after coating the first photoresist with the second photoresist.

4. The process according to claim 2, wherein coating of the second photoresist with a third photoresist is carried out after exposing the second photoresist, and wherein coating with a fourth photoresist or any further photoresist is preceded exposing the third photoresist or any further photoresist.

5. The process according to claim 1, wherein at least the first photoresist or the second photoresist or a further photoresist with more than one photoresist layer is applied one above the other in order to generate a defined height of a structure step of the at least one multi-layer photoresist structure.

6. The process according to claim 1, wherein the first photoresist has a sensitivity different from that of the second photoresist such that the first photoresist can be cured with the first exposure radiation to which the second photoresist does not react and vice versa.

7. The process according to claim 6, wherein the first photoresist is sensitive to the first exposure radiation having a longer wavelength exposure radiation and a higher exposure dose relative to the second exposure radiation having a shorter wavelength and a lower exposure dose to which the second photoresist is sensitive, and wherein the second photoresist is transparent and insensitive to the first exposure radiation of the first photoresist

8. The process according to claim 7, wherein sensitivities of the first photoresist and of the second photoresist differ by more than 20 nm in a wavelength range between 375 nm and 436 nm, and wherein exposure doses of the first photoresist and of the second photoresist differ in a range between 10 mJ/cm² and 2200 mJ/cm².

9. The process according to claim 6, further comprising selecting a third photoresist or further photoresist having a sensitivity differing in wavelength from the first photoresist and from the second photoresist in a wavelength range between 248 nm and 436 nm by more than 20 nm from the wavelengths of the first photoresist and the second photoresist and differing in an exposure dose in a range between 10 mJ/cm² and 2200 mJ/cm² from those of the first photoresist and the second photoresist.

10. The process according claim 1, wherein during developing of at least the first photoresist and second photoresist, the at least one multi-layer photoresist structure of the overlapping structure-forming regions of at least the first photoresist and the second photoresist remain on the substrate and form photoresist gaps) between adjacent multi-layer photoresist structures.

11. The process according to claim 10, further comprising depositing a metal or a metal alloy into the photoresist gaps between the three-dimensional photoresist structures.

12. The process according to claim 11, wherein the metal or the metal alloy is selected from copper, nickel, titanium, chromium, aluminum, palladium, tin, silver, gold and alloys thereof.

13. The process according to claim 1, further comprising generating the at least one multi-layer photoresist structure as elongated or closed layer stacks.

14. The process according to claim 10, wherein, further comprising removing the multi-layer photoresist structures by means of a resist developer after depositing a metal or a metal alloy in the gaps between the multi-layer photoresist structures by developing at least the first photoresist and the second photoresist, wherein metal molded bodies remain on the metal layer of the metal-clad substrate.

15. The process according to claim 14, further comprising etching a metal layer on the metal-clad substrate by means of a metal etchant at least in intermediate spaces between metal structures formed at the depositing step.

16. The process according to claim 15, further comprising continuing etching with the etchant adapted to the metal layer of the metal-clad substrate until the metal layer of the metal-clad substrate) is ablated so that the metal structures are singularized as the metal molded bodies.

17. The process according to claim 7, wherein sensitivities of the first photoresist and of the second photoresist differ by more than 30 nm in a wavelength range between 375 nm and 436 nm, and wherein exposure doses of the first photoresist and of the second photoresist differ in a range between 10 mJ/cm² and 2200 mJ/cm² by a factor of more than 4.

18. The process according to claim 6, further comprising selecting a third photoresist or further photoresist having a sensitivity differing in wavelength from the first photoresist and from the second photoresist in a wavelength range between 248 nm and 436 nm by more than 30 nm from the wavelengths of the first photoresist and the second photoresist and differing in an exposure dose by a factor of more than 4 in a range between 10 mJ/cm² and 2200 mJ/cm² from those of the first photoresist and the second photoresist.

19. The process according to claim 7, wherein sensitivities of the first photoresist and of the second photoresist differ by more than 20 nm in a wavelength range between 375 nm and 436 nm, and wherein exposure doses of the first photoresist and of the second photoresist differ in a range between 10 mJ/cm² and 2200 mJ/cm² by a factor of more than 4.

20. The process according to claim 6, further comprising selecting a third photoresist or further photoresist having a sensitivity differing in wavelength from the first photoresist and from the second photoresist in a wavelength range between 248 nm and 436 nm by more than 20 nm from the wavelengths of the first photoresist and the second photoresist and differing in an exposure dose by a factor of more than 4 in a range between 10 mJ/cm² and 2200 mJ/cm² from those of the first photoresist and the second photoresist.
